(19) United States
(12) Patent Application Publication
(10) Pub. No.: US 2011/0284871 A1
(43) Pub. Date: Nov. 24, 2011

(54) SILICON CARBIDE SUBSTRATE, SEMICONDUCTOR DEVICE, AND METHOD FOR MANUFACTURING SILICON CARBIDE SUBSTRATE

(75) Inventors: Shin HARADA, Osaka-shi (JP); Makoto Sasaki, Itami-shi (JP); Satomi Itoh, Osaka-shi (JP)

(73) Assignee: SUMITOMO ELECTRIC INDUSTRIES, LTD., Osaka-shi (JP)

(21) Appl. No.: 13/110,547

(22) Filed: May 18, 2011

(30) Foreign Application Priority Data
May 19, 2010 (JP) 2010-115027

(51) Int. Cl. H01L 29/16; H01L 21/20

(52) U.S. Cl. 257/77; 438/478; 257/E29.082; 257/E21.09

(57) ABSTRACT

A silicon carbide substrate includes a base layer made of silicon carbide, an SiC layer made of single crystal silicon carbide, arranged on the base layer, and having a concentration of inevitable impurities lower than the concentration of inevitable impurities in the base layer, and a cover layer made of silicon carbide, formed on a main surface of the base layer at a side opposite to the SiC layer, and having a concentration of inevitable impurities lower than the concentration of inevitable impurities in the base layer.

### BACKGROUND OF THE INVENTION

1. Field of the Invention

The present invention relates to a silicon carbide substrate, a semiconductor device, and a method for manufacturing a silicon carbide substrate. More particularly, the present invention relates to a silicon carbide substrate, a semiconductor device, and a method for manufacturing a silicon carbide substrate, capable of realizing reduction in the manufacturing cost of a semiconductor device employing a silicon carbide substrate.

2. Description of the Background Art

In recent years, the usage of silicon carbide (SiC) is continuing to advance as the material constituting a semiconductor device to allow high breakdown voltage, low loss, and usage under a high temperature environment. Silicon carbide is a wide band gap semiconductor having a band gap larger than that of silicon that is widely used as a conventional material constituting a semiconductor device. By employing silicon carbide for the material constituting a semiconductor device, a high breakdown voltage, a low ON resistance, and the like can be achieved for a semiconductor device. A semiconductor device employing silicon carbide as the material is advantageous in that, when used under a high temperature environment, reduction in the property is smaller as compared to a semiconductor device using silicon as the material.

Under such circumstances, the method for manufacturing silicon carbide crystal and a silicon carbide substrate used in manufacturing a semiconductor device have been the subject of various studies, leading to the proposal of various ideas (for example, refer to M. Nakabayashi, et al., “Growth of Crack-free 100 mm-diameter 4H—SiC Crystals with Low Micropipe Densities”, Mater. Sci. Forum, Vols. 600-603, 2009, pp. 3-6.

Silicon carbide does not have a liquid phase at normal pressure. The crystal growth temperature is extremely as high as 2000° C. or more. Furthermore, control and stabilization of the growing conditions are difficult to achieve. It is therefore difficult to increase the diameter while maintaining high quality for the silicon carbide crystal. It is not easy to obtain a large-diameter silicon carbide substrate with high quality. The difficulty in producing a silicon carbide substrate of a large diameter causes increase in the manufacturing cost of a silicon carbide substrate. There was also a problem that, in manufacturing semiconductor devices using such silicon carbide substrates, the number of production per batch is reduced, resulting in a higher manufacturing cost for semiconductor devices. It is considered that the manufacturing cost of a semiconductor device can be reduced by effectively utilizing silicon carbide crystal that has a high manufacturing cost in a substrate.

### SUMMARY OF THE INVENTION

In view of the foregoing, an object of the present invention is to provide a silicon carbide substrate, a semiconductor device, and a method for manufacturing a silicon carbide substrate, capable of realizing reduction in the manufacturing cost of a semiconductor device using a silicon carbide substrate.

A silicon carbide substrate of the present invention includes: a base layer made of silicon carbide; an SiC layer made of single crystal silicon carbide, arranged on the base layer, and having a concentration of inevitable impurities lower than the concentration of inevitable impurities of the base layer; and a cover layer made of silicon carbide, formed on a main surface of the base layer at a side opposite to the SiC layer, and having the concentration of inevitable impurities lower than the concentration of inevitable impurities of the base layer. As used herein, “inevitable impurity” refers to an impurity not intentionally introduced, but an impurity inevitably introduced due to the employed material and/or the manufacturing method.

As described above, it is difficult to increase the diameter of silicon carbide single crystal with high quality. In order to carry out manufacturing efficiently in a manufacturing process of a semiconductor device using a silicon carbide substrate, a substrate having a predetermined uniform shape and size is required. There is a possibility that even if silicon carbide single crystal of high quality (for example, silicon carbide single crystal having a low concentration of inevitable impurities and low defect density) is obtained, a region that cannot be processed to take a predetermined shape or the like such as by cutting cannot be utilized efficiently.

In a silicon carbide substrate of the present invention, an SiC layer made of single crystal silicon carbide having a concentration of inevitable impurities lower than that of the base layer is arranged on the base layer made of silicon carbide. A base layer made of low-quality silicon carbide crystal, having a high concentration of inevitable impurities and defect density, can be formed in a predetermined shape and size, while silicon carbide single crystal of high quality, but not realized in a desired shape and the like, can be arranged as an SiC layer on the base layer. Such a silicon carbide substrate can render the manufacturing of a semiconductor device efficient since the silicon carbide substrate has a predetermined uniform shape and size as a whole. Moreover, since a semiconductor device can be manufactured using such an SiC layer of high quality for the silicon carbide substrate, the silicon carbide single crystal can be utilized effectively. As a result, there can be provided a silicon carbide substrate that can realize reduction in the manufacturing cost of a semiconductor device using a silicon carbide substrate according to the present invention.

The SiC layer set forth above may be made of single crystal silicon carbide different from that of the base layer. The state of the SiC layer being formed of single crystal silicon carbide different from that of the base layer includes the case where the base layer is made of silicon carbide other than a single crystal such as polycrystal, amorphous, sintered compact and the like, and the case where the base layer is made of single crystal silicon carbide, differing from the crystal of the SiC layer. The state of the base layer and the SiC layer being made of different crystal implies the case where there is an interface between the base layer and SiC layer, and the defect density differs between one side and the other side of the interface. The defect density may be discontinuous at the interface.

Further, by lowering the purity of the material of the base layer, the manufacturing cost of the base layer, and in turn of the silicon carbide substrate, can be reduced. However, the concentration of inevitable impurities in the base layer will be increased. The inevitable impurities introduced into the base layer may be mixed into the semiconductor device produced using a silicon carbide substrate, leading to the possibility of inconvenience such as reduction in property. Specifically, in manufacturing a MOSFET (Metal Oxide Semiconductor Field Effect Transistor) using a silicon carbide substrate, for example, inevitable impurities may be introduced into the gate oxide film during production thereof.

In the silicon carbide substrate of the present invention, a cover layer having a concentration of inevitable impurities lower than that of the base layer is formed on a main surface of the base layer at a side opposite to the SiC layer. Therefore, even in the case where a base layer having a high concentration of inevitable impurities is employed, the main surface of the base layer will be covered with a cover layer. As a result, introduction of inevitable impurities into a semiconductor device caused by separation of inevitable impurities from the main surface of the base layer is suppressed, avoiding the aforementioned occurrence of inconvenience.

In the silicon carbide substrate set forth above, the base layer and the cover layer may have the same type conductivity. In the silicon carbide substrate set forth above, the concentration of conductivity type determination impurities of the cover layer may be higher than 1×10¹⁸ cm⁻³. Further, in the silicon carbide substrate, the base layer may be thicker than the cover layer.

Thus, there can be provided a silicon carbide substrate suitable for manufacturing a vertical semiconductor device in which current flows in the thickness direction of the substrate. In the present application, “conductivity type determination impurity” refers to an impurity intentionally introduced into silicon carbide for the purpose of controlling the conductivity type of silicon carbide.

In the silicon carbide substrate set forth above, the concentration of the conductivity type determination impurities in the base layer can be set higher than 2×10¹⁹ cm⁻³, and the concentration of the conductivity type determination impurities in the SiC layer can be set higher than 5×10¹⁸ cm⁻³ and lower than 2×10¹⁹ cm³.

The inventors of the present invention carried out detailed study on measures for lowering the resistivity in the thickness direction while suppressing generation of a stacking defect caused by thermal treatment. They found that if the concentration of the conductivity type determination impurities is less than 2×10¹⁹ cm⁻³, generation of a stacking defect due to thermal treatment can be suppressed while it is difficult to suppress stacking defect if the concentration exceeds 2×10¹⁹ cm³. Therefore, by providing a layer (base layer) having a concentration of conductivity type determination impurities higher than 2×10¹⁹ cm⁻³ and of low resistivity on the silicon carbide substrate, and arranging a layer (SiC layer) having a concentration of conductivity type determination impurities lower than 2×10¹⁹ cm³ on the base layer, generation of a stacking defect in at least the SiC layer can be suppressed even in the case where thermal treatment is performed subsequently in the device process. By producing a semiconductor device having a semiconductor layer made of silicon carbide on the SiC layer by epitaxial growth, the resistivity in the silicon carbide substrate can be lowered by virtue of the presence of the base layer, while suppressing the effect of a stacking defect that may be generated in the base layer upon the semiconductor device property. In the case where the concentration of the conductivity type determination impurities in the SiC layer is less than or equal to 5×10¹⁸ cm⁻³, the resistivity of the SiC layer may become too high.

By the configuration set forth above, there can be provided a silicon carbide substrate capable of lowering the resistivity in the thickness direction while suppressing generation of a stacking defect caused by thermal treatment.

The silicon carbide substrate further includes an epitaxial growth layer made of single crystal silicon carbide, on the SiC layer. The stacking defect density in the epitaxial growth layer may be lower than the stacking defect density in the base layer.

In forming an epitaxial growth layer on the SiC layer, thermal cleaning of the silicon carbide substrate and/or heating of the substrate for epitaxial growth is required. Even if a stacking defect is generated in the base layer by such heating, generation of a stacking defect in at least the SiC layer can be suppressed by setting the concentration of the conductivity type determination impurities of the base layer higher than 2×10¹⁹ cm⁻³, and the concentration of the conductivity type determination impurities of the SiC layer higher than 5×10¹⁸ cm⁻³ and lower than 2×10¹⁹ cm⁻³. Thus, generation of a stacking defect in the epitaxial growth layer formed on the SiC layer can be suppressed. As a result, the silicon carbide substrate allows production of a semiconductor device having reduction in the breakdown voltage and increase of leakage current suppressed by suppressing generation of a stacking defect in the epitaxial growth layer while lowering the resistivity. The epitaxial growth layer can be used as a buffer layer, and/or a breakdown voltage holding layer (drift layer) in the semiconductor device.

In the silicon carbide substrate set forth above, the conductivity type determination impurities in the base layer may differ from the conductivity type determination impurities in the SiC layer. Accordingly, there can be provided a silicon carbide substrate including appropriate conductivity type determination impurities according to the object of usage.

In the silicon carbide substrate set forth above, the conductivity type determination impurities in the base layer include nitrogen or phosphorus, whereas the conductivity type determination impurities in the SiC layer include nitrogen or phosphorus. Nitrogen and phosphorus are suitable as the conductivity type determination impurities supplying electrons as the majority carrier to silicon carbide.

In the above-described silicon carbide substrate, the SiC layer set forth above may be aligned in plurality in plan view. From another standpoint of description, a plurality of SiC layers may be arranged along the main surface of the base layer.

A substrate made of single crystal silicon carbide cannot readily be increased in diameter while maintaining high quality. By arranging a plurality of SiC layers picked from silicon carbide single crystal of high quality in plan view on the base layer of a large diameter, a silicon carbide substrate that can be handled as a large-diameter substrate having an SiC layer of high quality can be obtained. By using such a silicon carbide substrate, the manufacturing process of a semiconductor device can be rendered efficient. For the purpose of rendering the manufacturing process of a semiconductor device efficient, SiC layers adjacent to each other among the plurality of SiC layers are preferably arranged in contact with each other. Specifically, the plurality of SiC layers are preferably aligned in a matrix when in plan view. Further, the end faces of adjacent SiC layers are preferably substantially perpendicular to the main surface of the relevant SiC layer. This facilitates the manufacturing of a silicon carbide substrate. The end face and the main surface can be determined to be substantially perpendicular if the angle between the end face and the main surface is greater than or equal to 85° and less than or equal to 95°.

In the silicon carbide substrate, the base layer may be made of single crystal silicon carbide, and the full width at half maximum of the x-ray rocking curve of the SiC layer may be smaller than the full width at half maximum of the x-ray rocking curve of the base layer.

Accordingly, in the silicon carbide substrate of the present invention, an SiC layer having a full width at half maximum of the x-ray rocking curve smaller than that of the base layer, i.e. of high crystallinity, but not having a desired shape and the like realized, can be arranged on a base layer formed to take a shape and size suitable for manufacturing a semiconductor device. Such a silicon carbide substrate can render effective the manufacturing of a semiconductor device since it has a predetermined uniform shape and size as a whole. Since a semiconductor device can be manufactured using an SiC layer of high quality of the silicon carbide substrate, single crystal silicon carbide of high quality can be utilized effectively. As a result, the manufacturing cost of a semiconductor device using a silicon carbide substrate can be reduced.

In the silicon carbide substrate set forth above, the base layer is made of single crystal silicon carbide, and the micropipe density of the SiC layer may be lower than the micropipe density of the base layer.

Further, in the silicon carbide substrate set forth above, the base layer is made of single crystal silicon carbide, and the dislocation density of the SiC layer may be lower than the dislocation density of the base layer.

Further, in the silicon carbide substrate set forth above, the base layer is made of single crystal silicon carbide, and the threading screw dislocation density of the SiC layer may be lower than the threaded screw dislocation density of the base layer.

Further, in the silicon carbide substrate set forth above, the base layer is made of single crystal silicon carbide, and the threading edge dislocation density of the SiC layer may be lower than the threading edge dislocation density of the base layer.

Further, in the silicon carbide substrate set forth above, the base layer is made of single crystal silicon carbide, and the basal plane dislocation density of the SiC layer may be lower than the basal plane dislocation density of the base layer.

Further, in the silicon carbide substrate set forth above, the base layer is made of single crystal silicon carbide, and the composite dislocation density of the SiC layer may be lower smaller than the composite dislocation density of the base layer.

Further, in the silicon carbide substrate set forth above, the base layer is made of single crystal silicon carbide, and the stacking defect density of the SiC layer may be lower than the stacking defect density of the base layer.

Further, in the silicon carbide substrate set forth above, the base layer is made of single crystal silicon carbide, and the point defect density of the SiC layer may be lower than the point defect density of the base layer.

Accordingly, an SiC layer having lower micropipe density, dislocation density, and the like (threading screw dislocation density, threading edge dislocation density, basal plane dislocation density, composite dislocation density, stacking defect density, point defect density, and the like), i.e. of high quality, but not realized in a predetermined shape and size, can be arranged on a base layer formed to take a predetermined shape and size suitable for manufacturing a semiconductor device, but of relatively low quality. In such a silicon carbide substrate, the manufacture of a semiconductor device can be rendered efficient since the silicon carbide substrate has a predetermined uniform shape and size suitable for manufacturing a semiconductor device as a whole. Since a semiconductor device can be manufactured using such an SiC layer of high quality of the silicon carbide substrate, single crystal silicon carbide of high quality can be utilized effectively. As a result, reduction in the manufacturing cost of a semiconductor device using a silicon carbide substrate can be realized.

In the silicon carbide substrate set forth above, the base layer may include a single crystal layer made of single crystal silicon carbide so as to include the main surface facing the SiC layer. Accordingly, in the manufacture of a semiconductor device using a silicon carbide substrate, a readily handable state of great thickness can be maintained at the initial stage of the manufacturing process. Moreover, by removing the region of the base layer other than the single crystal layer during the manufacturing process, only the single crystal layer among the base layer can be left in the semiconductor device. Accordingly, there can be manufactured a semiconductor device of high quality while facilitating the handling of a silicon carbide substrate in the manufacturing process.

In the silicon carbide substrate set forth above, the full width at half maximum of the x-ray rocking curve of the SiC layer may be smaller than the full width at half maximum of the x-ray rocking curve of the single crystal layer. By arranging an SiC layer having a full width at half maximum of an x-ray rocking curve smaller than that of the single crystal layer of the base layer, i.e. of high crystallinity, a silicon carbide substrate that allows manufacturing a semiconductor device of high quality can be obtained.

In the silicon carbide substrate set forth above, the micropipe density of the SiC layer may be lower than the micropipe density of the single crystal layer.

In the silicon carbide substrate set forth above, the dislocation density of the SiC layer may be lower than the dislocation density of the single crystal layer.

In the silicon carbide substrate set forth above, the threading screw dislocation density of the SiC layer may be lower than the threading screw dislocation density of the single crystal layer.

In the silicon carbide substrate set forth above, the threading edge dislocation density of the SiC layer may be lower than threading edge dislocation density of the single crystal layer.

In the silicon carbide substrate set forth above, the basal plane dislocation density of the SiC layer may be lower than basal plane dislocation density of the single crystal layer.

In the silicon carbide substrate set forth above, the composite dislocation density of the SiC layer may be lower than the composite dislocation density of the single crystal layer.

In the silicon carbide substrate set forth above, the stacking defect density of the SiC layer may be lower than the stacking defect density of the single crystal layer.

In the silicon carbide substrate set forth above, the point defect density of the SiC layer may be lower than the point defect density of the single crystal layer.

By arranging an SiC layer having a lower defect density such as micropipe density, dislocation density, and the like (threading screw dislocation density, threading edge dislocation density, basal plane dislocation density, composite dislocation density, stacking defect density, point defect density, and the like) than that of the single crystal layer of the base layer, a silicon carbide substrate that allows manufacturing a semiconductor device of high quality can be obtained.

In the silicon carbide substrate set forth above, the main surface of the SiC layer at the side opposite to the base layer may have an off angle relative to the {0001} plane greater than or equal to 50° and less than or equal to 65°.

By growing the hexagonal single crystal silicon carbide in the <0001> direction, a single crystal of high quality can be produced efficiently. From the silicon carbide crystal grown in the <0001> direction, a silicon carbide substrate having the {0001} plane as the main surface can be picked efficiently. By using a silicon carbide substrate having a main surface whose off angle relative to the plane orientation of {0001} is greater than or equal to 50° and less than or equal to 65°, a semiconductor device of high performance can be manufactured.

Specifically, a silicon carbide substrate employed in the production of a MOSFET, for example, generally has a main surface whose off angle to the plane orientation of {0001} is less than or equal to approximately 8°. On the main surface, a semiconductor layer is formed by epitaxial growth, and an oxide film, an electrode, and the like are formed on the semiconductor layer, to obtain a MOSFET. In this MOSFET, a channel region is formed at a region including the interface between the semiconductor layer and oxide film. In the MOSFET having such a structure, many interface states are formed in the proximity of the interface between the semiconductor layer and oxide film where the channel region is formed due to the main surface of the substrate having an off angle relative to the plane orientation of {0001} being less than or equal to approximately 8°, blocking the movement of the carriers to reduce the channel mobility.

By setting the off angle of the main surface of the SiC layer at the side opposite to the base layer, relative to the {0001} plane, greater than or equal to 50° and less than or equal to 65°, formation of the aforementioned interface states is reduced, allowing a MOSFET reduced in the ON resistance to be produced.

In the silicon carbide substrate set forth above, the angle between the off orientation of the main surface of the SiC layer at the side opposite to the base layer and the <1-100> direction may be less than or equal to 5°.

The <1-100> orientation is the typical off orientation in a silicon carbide substrate. By setting the variation in the off orientation caused by variation in the slicing process in the manufacturing step of a substrate less than or equal to 5°, the epitaxial growth of a semiconductor layer on the silicon carbide substrate can be facilitated.

In the silicon carbide substrate set forth above, the off angle of the main surface of the SiC layer at the side opposite to the base layer, relative to the {03-38} plane in the <1-100> direction may be greater than or equal to −3° and less than or equal to 5°. Accordingly, the channel mobility when a MOSFET is produced using a silicon carbide substrate can be further improved. The off angle relative to the plane orientation of {03-38} being set greater than or equal to −3° and less than or equal to 5° is based on the fact that high mobility can be obtained particularly in this range as a result of studying the relationship between the channel mobility and the off angle.

As used herein, “the off angle relative to the {03-38} plane in the <1-100> direction” refers to an angle between an orthogonal projection of the normal line of the aforementioned main surface to a plane defined by the <1-100> direction and <0001> direction, and the normal line of the {03-38} plane. The sign is positive in the case where the aforementioned orthogonal projection approaches in parallel with the <1-100> direction whereas the sign is negative when the aforementioned orthogonal projection approaches in parallel with the <0001> direction.

The plane orientation of the main surface set forth above is preferably substantially {03-38}, more preferably {03-38}. The plane orientation of the main surface being substantially {03-38} implies that the plane orientation of the main surface of the substrate is included in the range of the off angle where the plane orientation is substantially {03-38} in consideration of the processing accuracy and the like of the substrate. The off angle range in this case is within the range of ±2° to {03-38}. Accordingly, the aforementioned channel mobility can be further improved. In the silicon carbide substrate set forth above, the angle between the off orientation of the main surface of the SiC layer at the side opposite to the base layer and the <11-20> orientation may be less than or equal to 5°.

Likewise with the <1-100> direction set forth above, <11-20> is a typical off orientation in a silicon carbide substrate. By setting the variation of the off orientation caused by variation in the slicing process and the like in a substrate manufacturing step to ±5°, the epitaxial growth of a semiconductor layer on the SiC layer can be facilitated.

A semiconductor device of the present invention includes a silicon carbide substrate, a semiconductor layer formed by epitaxial growth on the silicon carbide substrate, and an electrode formed on the semiconductor layer. The silicon carbide substrate is a silicon carbide substrate of the present invention set forth above.

By the inclusion of a silicon carbide substrate of the present invention set forth above in the semiconductor device of the present invention, there can be provided a semiconductor device capable of realizing reduction in the manufacturing cost of a semiconductor device using a silicon carbide substrate.

A method for manufacturing a silicon carbide substrate of the present invention includes the steps of preparing an SiC substrate made of single crystal silicon carbide; arranging a silicon carbide source facing one of main surfaces of the SiC substrate; forming a base layer made of silicon carbide and having a concentration of inevitable impurities higher than the concentration of inevitable impurities in the SiC substrate, in contact with one of main surfaces of the SiC substrate, by heating the silicon carbide source; and forming a cover layer made of silicon carbide and having a concentration of inevitable impurities lower than the concentration of inevitable impurities of the base layer, on the main surface of the base layer at a side opposite to the SiC substrate. According to the method for manufacturing a silicon carbide substrate of the present invention, a silicon carbide substrate of the present invention can be manufactured readily.

In the manufacturing method for a silicon carbide substrate set forth above, the cover layer may be formed by CVD (Chemical Vapor Deposition) epitaxial growth. The CVD epitaxial growth is suitable as a method for forming a cover layer having superior adherence with the base layer.

In the method for manufacturing a silicon carbide substrate set forth above, the step of polishing a main surface of the base layer at a side opposite to the SiC substrate may be included, prior to the step of forming a cover layer. Accordingly, forming a cover layer in a subsequent step is facilitated.

As apparent from the description set forth above, according to a silicon carbide substrate, a semiconductor device, and a method for manufacturing a silicon carbide substrate of the present invention, there can be provided a silicon carbide substrate, a semiconductor device, and a method for manufacturing a silicon carbide substrate, capable of realizing reduction in the manufacturing cost of a semiconductor device using a silicon carbide substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a configuration of a silicon carbide substrate.

FIG. 2 is a schematic sectional view representing a configuration of a silicon carbide substrate having an epitaxial growth layer formed.

FIG. 3 is a flowchart schematically representing a method for manufacturing a silicon carbide substrate.

FIG. 4 is a flowchart schematically representing another method for manufacturing a silicon carbide substrate.

FIGS. 5, 6, and 7 are schematic sectional views for describing a method for manufacturing a silicon carbide substrate.

FIG. 8 is a schematic sectional view representing another configuration of a silicon carbide substrate.

FIG. 9 is a schematic sectional view representing a further configuration of a silicon carbide substrate.

FIG. 10 is a flowchart schematically representing a method for manufacturing the silicon carbide substrate of FIG. 9.

FIG. 11 is a schematic sectional view representing still another configuration of a silicon carbide substrate.

FIG. 12 is a flowchart schematically representing a method for manufacturing the silicon carbide substrate of FIG. 11.

FIG. 13 is a schematic sectional view representing still another configuration of a silicon carbide substrate.

FIG. 14 is a flowchart schematically representing a method for manufacturing the silicon carbide substrate of FIG. 13.

FIG. 15 is a schematic sectional view for describing a method for manufacturing the silicon carbide substrate of FIG. 13.

FIG. 16 is a schematic sectional view representing a configuration of a vertical MOSFET.

FIG. 17 is a flowchart schematically representing a method for manufacturing a vertical MOSFET.

FIGS. 18, 19, 20 and 21 are schematic sectional views for describing a method for manufacturing a vertical MOSFET.

### DESCRIPTION OF THE PREFERRED EMBODIMENTS

Embodiments of the present invention will be described hereinafter with reference to the drawings. In the drawings, the same or corresponding elements have the same reference characters allotted, and description thereof will not be repeated.

### First Embodiment

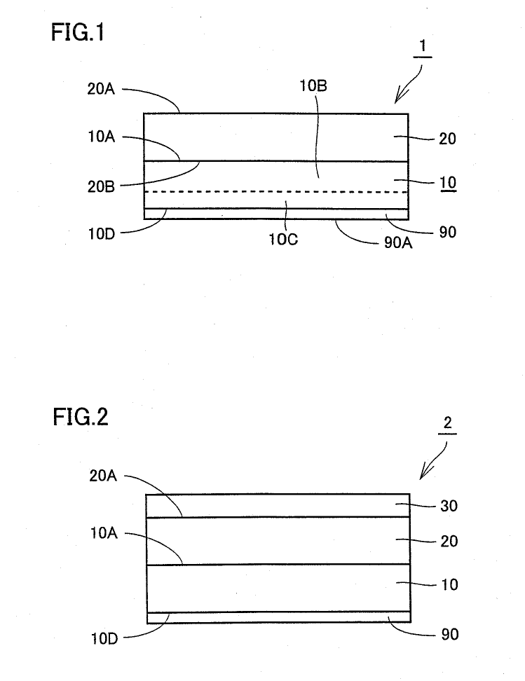

A first embodiment that is an exemplified embodiment of the present invention will be described. Referring to FIG. 1, a silicon carbide substrate 1 of the present embodiment includes a base layer 10 made of silicon carbide, an SiC layer 20 made of single crystal silicon carbide, arranged on a main surface 10A of base layer 10, and having a concentration of inevitable impurities lower than that of base layer 10, and a cover layer 90 made of silicon carbide, formed on a main surface 10D of base layer 10 at a side opposite to SiC layer 20, having a concentration of inevitable impurities lower than the concentration of inevitable impurities of base layer 10.

In silicon carbide substrate 1 of the present embodiment, SiC layer 20 made of single crystal silicon carbide having a concentration of inevitable impurities lower than that of base layer 10 is arranged on main surface 10A of base layer 10 made of silicon carbide. Accordingly, base layer 10 made of low-quality silicon carbide crystal, having a high concentration of inevitable impurities and defect density, can be formed in a predetermined shape and size suitable for manufacturing a semiconductor device, whereas silicon carbide single crystal of high quality, but not realized in a desired shape and the like, can be arranged as SiC layer 20 on base layer 10. As a result, silicon carbide substrate 1 of the present embodiment allows realizing reduction in the manufacturing cost of a semiconductor device using a silicon carbide substrate. SiC layer 20 may be formed of single crystal silicon carbide differing from that of base layer 10.

In silicon carbide substrate 1 of the present embodiment, cover layer 90 made of silicon carbide and having a concentration of inevitable impurities lower than that of base layer 10 is formed on main surface 10D of base layer 10 at the side opposite to SiC layer 20. Therefore, even in the case where a base layer 10 of high concentration of inevitable impurities is employed, the main surfaces of base layer 10 will be covered with cover layer 90 and SiC layer 20, respectively. As a result, in manufacturing a semiconductor device using silicon carbide substrate 1, introduction of inevitable impurities to the semiconductor device caused by separation of inevitable impurities from main surfaces 10A and 10D of base layer 10 is suppressed.

Base layer 10 and cover layer 90 may be of the same conductivity type. The concentration of conductivity type determination impurities in cover layer 90 may be higher than 1×10¹⁸ cm⁻³. Base layer 10 may be thicker than cover layer 90. By employing at least one of these elements in the configuration, silicon carbide substrate 1 is rendered suitable for manufacturing a vertical semiconductor device having current flowing in the thickness direction of substrate.

The concentration of conductivity type determination impurities in base layer 10 can be set higher than 2×10¹⁹ cm⁻³, and the concentration of conductivity type determination impurities in SiC layer 20 can be set higher than 5×10¹⁸ cm⁻³ and less than 2×10¹⁹ cm⁻³. Accordingly, silicon carbide substrate 1 allows the resistivity in the thickness direction to be reduced while suppressing generation of a stacking defect caused by thermal treatment. In this case, even if an epitaxial growth layer 30 made of single crystal silicon carbide is formed on a main surface 20A of SiC layer 20 at a side opposite to base layer 10, as shown in FIG. 2, the stacking defect that may occur at base layer 10 will not be propagated to epitaxial growth layer 30. Accordingly, the stacking defect density in epitaxial growth layer 30 can be set smaller than that of base layer 10.

In silicon carbide substrate 1, the conductivity type determination impurities in base layer 10 may differ from those in SiC layer 20. Accordingly, there can be obtained a silicon carbide substrate with conductivity type determination impurities suitable for the object of usage. Further, the conductivity type determination impurities in base layer 10 may be nitrogen and phosphorus. The conductivity type determination impurities in SiC layer 20 may be nitrogen or phosphorus.

In silicon carbide substrate 1, base layer 10 is made of single crystal silicon carbide, and the full width at half maximum of the x-ray rocking curve of SiC layer 20 may be smaller than the full width at half maximum of the x-ray rocking curve of base layer 10.

Accordingly, single crystal silicon carbide of relatively low crystallinity, but having a predetermined uniform shape and size, can be used as base layer 10 of silicon carbide substrate 1, whereas single crystal silicon carbide of high quality, but not realized in a desired shape and the like, can be effectively used as SiC layer 20. By producing a semiconductor device using such silicon carbide substrate 1, the manufacturing cost of the semiconductor device can be reduced.

In silicon carbide substrate 1, base layer 10 is made of single crystal silicon carbide, and the micropipe density of SiC layer 20 may be lower than that of base layer 10. In silicon carbide substrate 1, base layer 10 is made of single crystal silicon carbide, and the dislocation density of SiC layer 20 may be lower than that of base layer 10. In silicon carbide substrate 1, base layer 10 is made of single crystal silicon carbide, and the threading screw dislocation density of SiC layer 20 may be lower than that of base layer 10. In silicon carbide substrate 1, base layer 10 is made of single crystal silicon carbide, and the threading edge dislocation density of SiC layer 20 may be lower than that of base layer 10. In silicon carbide substrate 1, base layer 10 is made of single crystal silicon carbide, and the basal plane dislocation density of SiC layer 20 may be lower than that of base layer 10. In silicon carbide substrate 1, base layer 10 is made of single crystal silicon carbide, and the composite dislocation density of SiC layer 20 may be lower than that of base layer 10. In silicon carbide substrate 1, base layer 10 is made may be made of single crystal silicon carbide, and the stacking defect dislocation density of SiC layer 20 may be lower than that of base layer 10. In silicon carbide substrate 1, base layer 10 is made of single crystal silicon carbide, and the point defect density of SiC layer 20 may be lower than that of base layer 10.

Accordingly, single crystal silicon carbide of low quality having a relatively high micropipe density and defect density, taking a predetermined uniform shape and size can be used as base layer 10 of silicon carbide substrate 1, whereas single crystal silicon carbide having lower micropipe density and/or defect density, i.e. of high quality, but not realized in a predetermined shape and size, can be used effectively as SiC layer 20. As a result, by producing a semiconductor device using such a silicon carbide substrate 1, the manufacturing cost of a semiconductor device can be reduced.

In silicon carbide substrate 1, base layer 10 may include a single crystal layer 10B made of single crystal silicon carbide to include a main surface 10A at a side facing SiC layer 20. Accordingly, in manufacturing a semiconductor device using silicon carbide substrate 1, a readily handable state of great thickness can be maintained at the initial stage of the manufacturing process. Moreover, by removing a non-single crystal region 10C that is a region of base layer 10 other than the single crystal layer during the manufacturing process, only single crystal layer 10B in base layer 10 can be left in the semiconductor device. Accordingly, there can be manufactured a semiconductor device of high quality while facilitating the handling of silicon carbide substrate 1 in the manufacturing process.

Moreover, in silicon carbide substrate 1, the full width at half maximum of the x-ray rocking curve of SiC layer 20 may be smaller than the full width at half maximum of the x-ray rocking curve of single crystal layer 10B. By arranging SiC layer 20 having a full width at half maximum of the x-ray rocking curve smaller than that of single crystal layer 10B of base layer 10, i.e. of high crystallinity, a silicon carbide substrate 1 allowing a semiconductor device of high quality to be manufactured can be obtained. In silicon carbide substrate 1, the micropipe density of SiC layer 20 may be lower than that of single crystal layer 10B. In silicon carbide substrate 1, the dislocation density of SiC layer 20 may be lower than that of single crystal layer 10B. In silicon carbide substrate 1, the threading screw dislocation density of SiC layer 20 may be lower than that of single crystal layer 20B. In silicon carbide substrate 1, the threading edge dislocation density of SiC layer 20 may be lower than that of single crystal layer 10B. In silicon carbide substrate 1, the basal plane dislocation density of SiC layer 20 may be lower than that of single crystal layer 10B. In silicon carbide substrate 1, the composite dislocation density of SiC layer 20 may be smaller than that of single crystal layer 10B. In silicon carbide substrate 1, the stacking defect density of SiC layer 20 may be smaller than that of single crystal layer 10B. In silicon carbide substrate 1, the point defect density of SiC layer 20 may be lower than that of single crystal layer 10B.

Thus, by arranging SiC layer 20 having the defect density such as the micropipe density, threading screw dislocation density, threading edge dislocation density, basal plane dislocation density, composite dislocation density, stacking defect density, and point defect density lower as compared to single crystal layer 10B of base layer 10, a silicon carbide substrate 1 allowing the manufacture of a semiconductor device of high quality can be obtained.

In silicon carbide substrate 1, main surface 20A of SiC layer 20 may have an off angle relative to the {0001} plane greater than or equal to 50° and less than or equal to 65°. By producing a MOSFET using such a silicon carbide substrate 1, a MOSFET having the formation of interface states at the channel region reduced, and having an ON resistance reduced can be obtained. In consideration of facilitating manufacturing, main surface 20A of SiC layer 20 may be the {0001} plane.

Further, the angle between the off orientation of main surface 20A of SiC layer 20 and the <1-100> direction may be less than or equal to 5°. The <1-100> direction is the typical off orientation in a silicon carbide substrate. By setting the variation in the off orientation caused by variation in the slicing process and the like at a substrate manufacturing process less than or equal to 5°, epitaxial growth of a semiconductor layer on silicon carbide substrate 1 can be facilitated.

In silicon carbide substrate 1, the off angle relative to the {03-38} plane in the <1-100> direction of main surface 20A of SiC layer 20 is preferably set to at least −3° and not more than 5°. Accordingly, the channel mobility when a MOSFET is produced using silicon carbide substrate 1 can be further improved.

In silicon carbide substrate 1 set forth above, the angle between the off orientation of main surface 20A of silicon carbide layer 20 and the {11-20} direction may be less than or equal to 5°.

<11-20> is a typical off orientation in a silicon carbide substrate. By setting variation in the off orientation caused by variation in the slicing process and the like in the method for manufacturing a substrate to ±5°, epitaxial growth of the semiconductor layer on silicon carbide substrate 1 can be facilitated.

At silicon carbide substrate 1, SiC layer 20 may be made of single crystal silicon carbide differing from that of base layer 10.

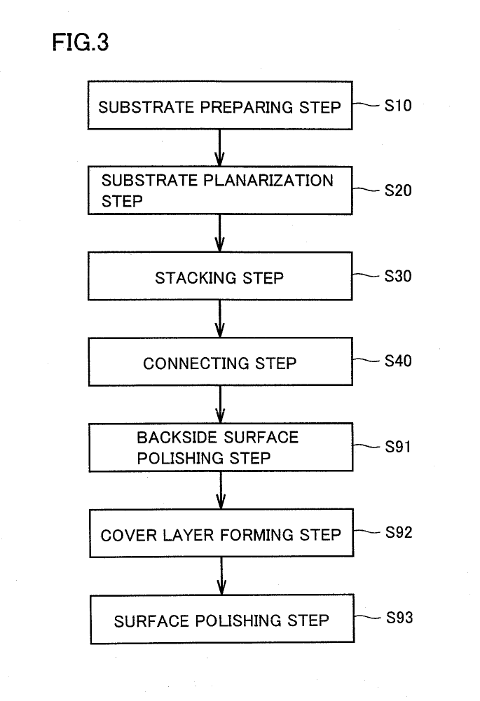

An example of a method for manufacturing silicon carbide substrate 1 will be described hereinafter. Referring to FIG. 3, in a method for manufacturing a silicon carbide substrate of the present embodiment, first a substrate preparing step is performed as a step S10. In this step S10, base substrate 10 made of single crystal silicon carbide and SiC substrate 20, for example, shown in FIG. 1, are prepared. Base substrate 10 is a silicon carbide source in the present embodiment. The concentration of inevitable impurities in SiC substrate 20 is lower than the concentration of inevitable impurities in base substrate 10.

At this stage, the plane orientation for the main surface of SiC substrate 20 is selected in accordance with the desired plane orientation of main surface 20A, since the main surface of SiC substrate 20 will correspond to main surface 20A of SiC layer 20 obtained by the present manufacturing method (refer to FIG. 1). In the present embodiment, SiC substrate 20 having a main plane corresponding to the {03-38} plane, for example, is prepared. For base substrate 10, a substrate having a concentration of conductivity type determination impurities higher than 2×10¹⁹ cm⁻³, for example, can be employed. For SiC substrate 20, a substrate having a concentration of conductivity type determination impurities higher than 5×10¹⁸ cm⁻³ and smaller than 2×10¹⁹ cm⁻³ can be employed.

Then, as a step S20, a substrate planarization step is performed. In this step S20, the main surfaces of base substrate 10 and SiC substrate 20 (connecting faces) to be brought into contact with each other at a step S30 that will be described afterwards are planarized by polishing, for example. Step S20 is not a mandatory step. By performing this step, the gap between base substrate 10 and SiC substrate 20 facing each other is reduced such that the distance between base substrate 10 and SiC substrate 20 is rendered uniform. Therefore, the uniformity in the reaction (connection) in the connecting face at a step S40 that will be described afterwards is improved. As a result, the connection between base substrate 10 and SiC substrate 20 can be further ensured. To connect base substrate 10 with SiC substrate 20 more reliably, the surface roughness Ra of the connecting face is preferably less than 100 nm, more preferably less than 50 nm. By setting the surface roughness Ra of the connecting face less than 10 nm, the connection can be achieved further reliably.

It is to be noted that step S20 can be omitted and step S30 can be performed without having the main surfaces of base substrate 10 and SiC substrate 20 that are to be brought into contact with each other polished. This allows reduction in the manufacturing cost of silicon carbide substrate 1. From the standpoint of removing a damage layer formed in the proximity of the surface due to slicing or the like during production of base substrate 10 and SiC substrate 20, a step of removing the damage layer by etching, for example, can be performed instead of or after step S20, before proceeding to step S30 that will be described afterwards.

At step S30, a stacking step is performed. In this step S30, SiC substrate 20 is arranged on and in contact with the main surface of base substrate 10 to produce a stacked substrate. In other words, base substrate 10 serving as a silicon carbide source is arranged so as to face and come into contact with one main surface 20B of SiC substrate 20 (refer to FIG. 1).

Next, as a step S40, a connecting step is performed. In this step S40, base substrate 10 is connected with SiC substrate 20 by heating the above-described stacked substrate. Accordingly, a base layer 10 made of silicon carbide, having a concentration of inevitable impurities higher than that of SiC substrate 20, is formed to come into contact with one main surface 20B of SiC substrate 20. SiC substrate 20 corresponds to SiC layer 20 of the present embodiment (refer to FIG. 1).

At a step S91, a backside polishing step is performed. In this step S91, a main surface 10D of base layer 10 at a side opposite to SiC substrate 20 is polished. Although this step S91 is not mandatory, formation of a cover layer in a subsequent step S92 is facilitated by performing step S91.

At step S92, a cover layer forming step is performed. In this step S92, a cover layer 90 made of silicon carbide, and having a concentration of inevitable impurities lower than that of base layer 10 is formed on main surface 10D of base layer 10 at the side opposite to SiC layer 20. By the process set forth above, silicon carbide substrate 1 can be manufactured readily in the first embodiment. Moreover, a front side surface polishing step may be performed as necessary, at step S93. In this step S93, main surface 20A of SiC layer 20 at the side opposite to base layer 10 is polished. Although this step S93 is not mandatory, formation of an epitaxial growth layer on main surface 20A of SiC layer 20 is facilitated by performing step S93.

Moreover, single crystal silicon carbide can be grown epitaxially on the silicon carbide substrate set forth above to provide an epitaxial growth layer 30 on main surface 20A of SiC layer 20. Accordingly, silicon carbide substrate 2 shown in FIG. 2 can be manufactured.

In the stacked substrate produced at step S30, the gap formed between base substrate 10 and SiC substrate 20 is preferably less than or equal to 100 μm. Even if the planarity is high, base substrate 10 and SiC substrate 20 include a slight warpage, distortion, or the like. Therefore, a gap will be formed between base substrate 10 and SiC substrate 20 in the stacked substrate. If this gap exceeds 100 μm, there is a possibility of the connecting state between base substrate 10 and SiC substrate 20 being not uniform. Therefore, by setting the gap between base substrate 10 and SiC substrate 20 less than or equal to 100 μm, uniform connection between base substrate 10 and SiC substrate 20 can be achieved more reliably.

At a step S40, the stacked substrate may be heated in an atmosphere obtained by reducing the pressure of the atmosphere. Accordingly, the manufacturing cost of silicon carbide substrate 1 can be reduced. At step S40, the stacked substrate is preferably heated in a temperature range equal to or higher than the sublimation temperature of silicon carbide. Accordingly, the connection between base substrate 10 and SiC substrate 20 can be further ensured. Particularly, by setting the gap formed between base substrate 10 and SiC substrate 20 in the stacked substrate less than or equal to 100 μm, uniform connection can be achieved by sublimation of silicon carbide. Even in the case where step S20 is omitted and step S30 is performed without having the main surfaces of base substrate 10 and SiC substrate 20 that are to be brought into contact with each other polished, the connection between base substrate 10 and SiC substrate 20 can be facilitated.

The heating temperature of the stacked substrate at step S40 is preferably higher than or equal to 1800° C. and less than or equal to 2500° C. If the heating temperature is lower than 1800° C., the connection between base substrate 10 and SiC substrate 20 will be time consuming, reducing the manufacturing efficiency of silicon carbide substrate 1. If the heating temperature exceeds 2500° C., the surface of base substrate 10 and SiC substrate 20 will be roughened, leading to the possibility of increasing the generation of crystal defects in the produced silicon carbide substrate 1. In order to improve the manufacturing efficiency while further suppressing generation of a defect at silicon carbide substrate 1, the heating temperature of the stacked substrate at step S40 is preferably higher than or equal to 1900° C. and less than or equal to 2100° C. Further, in step S40, the stacked substrate may be heated under a pressure higher than 10⁻¹ Pa and lower than 10⁴ Pa. Accordingly, the connection can be performed with a simple device, and an atmosphere to perform the connection in a relatively short period of time can be obtained, allowing the manufacturing cost of silicon carbide substrate 1 to be reduced. The atmosphere during heating in step S40 may be an inert gas atmosphere. In the case where an inert gas atmosphere is employed, the atmosphere is preferably an inert gas atmosphere including at least one selected from the group consisting of argon, helium, and nitrogen.

In step S92, cover layer 90 may be formed by CVD epitaxial growth. Accordingly, cover layer 90 having superior adherence with base layer 10 can be formed. The method of forming of cover layer 90 is not limited to CVD epitaxial growth, and the sublimation technique, molecular beam epitaxy (MBE), sputtering, or the like may be employed.

### Second Embodiment

A second embodiment that is another embodiment of the present invention will be described hereinafter. Referring to FIG. 1, silicon carbide substrate 1 of the second embodiment has a configuration basically similar to that of silicon carbide substrate 1 of the first embodiment, and provides similar effects. Silicon carbide substrate 1 of the second embodiment differs from the first embodiment in the manufacturing method.

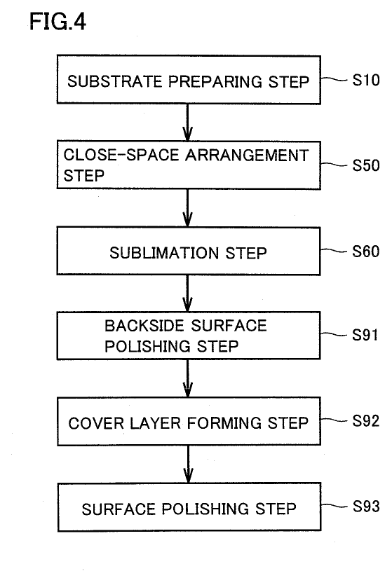

In a method for manufacturing silicon carbide substrate 1 in the second embodiment of FIG. 4, first a substrate preparing step is performed as step S10. At this step S10, an SiC substrate is prepared, likewise with the first embodiment, and a material substrate made of silicon carbide is prepared.

Referring to FIG. 4, a close-space arrangement step is performed at step S50. In this step S50 shown in FIG. 5, SiC substrate 20 and material substrate 11 are held by a first heater 81 and a second heater 82, respectively, arranged so as to face each other. In other words, material substrate 11 that is the silicon carbide source is arranged to face one main surface 20B of SiC substrate 20.

The appropriate value of the distance between SiC substrate 20 and material substrate 11 is considered to be related with the mean free path of the sublimation gas during heating in step S60 that will be described afterwards. Specifically, the average value of the distance between SiC substrate 20 and material substrate 11 can be set to be smaller than the mean free path of the sublimation gas during heating in step S60. For example, under the pressure of 1 Pa and temperature of 2000° C., the mean free path of the atoms and molecules is present in approximately several to several ten centimeters, depending upon the atomic radius and molecular radius, strictly speaking. Therefore, in practice, the aforementioned distance is preferably set less than or equal to several centimeters. More specifically, SiC substrate 20 and material substrate 11 are arranged in close proximity such that their main surfaces face each other with the distance therebetween greater than or equal to 1 μm and less than or equal to 1 cm. By setting the average value of the distance less than or equal to 1 cm, the film thickness distribution of base layer 10 formed in step S60 that will be described afterwards can be reduced. Furthermore, by setting the average value of the distance less than or equal to 1 mm, the film thickness distribution of base layer 10 formed in step S60 can be further reduced. Moreover, by setting the average value of the distance greater than or equal to 1 μm, sufficient space for sublimation of silicon carbide can be ensured. The aforementioned sublimation gas is formed by sublimation of solid silicon carbide, and includes Si, Si₂C and SiC₂, for example.

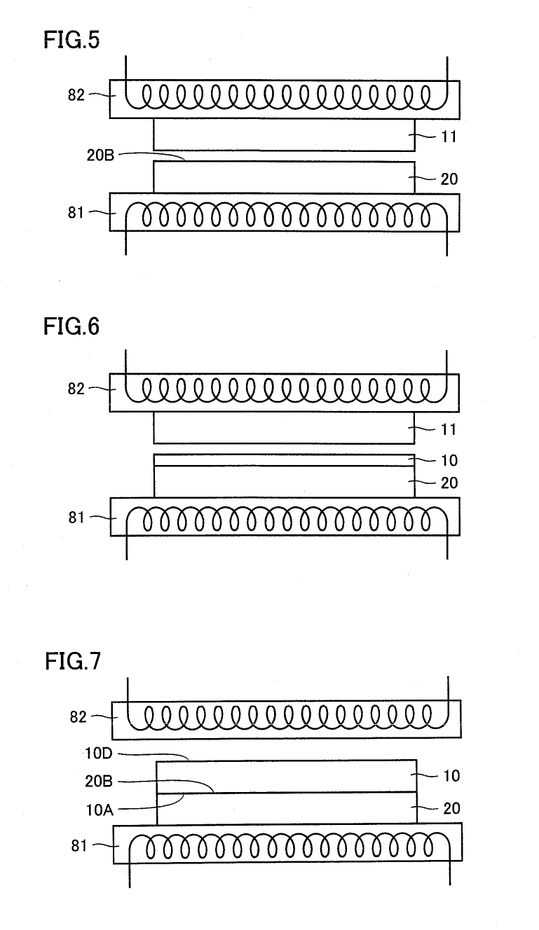

Then, a sublimation step is performed as step S60. In step S60, SiC substrate 20 is heated up to a predetermined substrate temperature by first heater 81. Material substrate 11 is heated up to a predetermined material temperature by second heater 82. The heating of material substrate 11 up to the material temperature causes sublimation of silicon carbide from the surface of material substrate 11. At this stage, the substrate temperature is set lower than the material temperature. Specifically, the substrate temperature is set lower than at least 1° C. and not more than 100° C. than the material temperature. The substrate temperature is, for example, higher than or equal to 1800° C. and less than or equal to 2500° C. Accordingly, silicon carbide attaining a gaseous state by sublimation from material substrate 11 arrives at the surface of SiC substrate 20 to attain a solid phase to form base layer 10, as shown in FIG. 6. By maintaining this state, the silicon carbide constituting material substrate 11 is completely sublimed to move onto the surface of SiC substrate 20, as shown in FIG. 7. Thus, step S60 is completed. Then, SiC substrate 20 having base layer 10 formed is detached from first heater 81. A step S91 is performed as necessary, likewise with the first embodiment, and then a step S92 is performed. By the process set forth above, silicon carbide substrate 1 shown in FIG. 1, including SiC substrate 20 as SiC layer 20, is completed. Likewise with the first embodiment, step S93 may be performed, as necessary.

### Third Embodiment

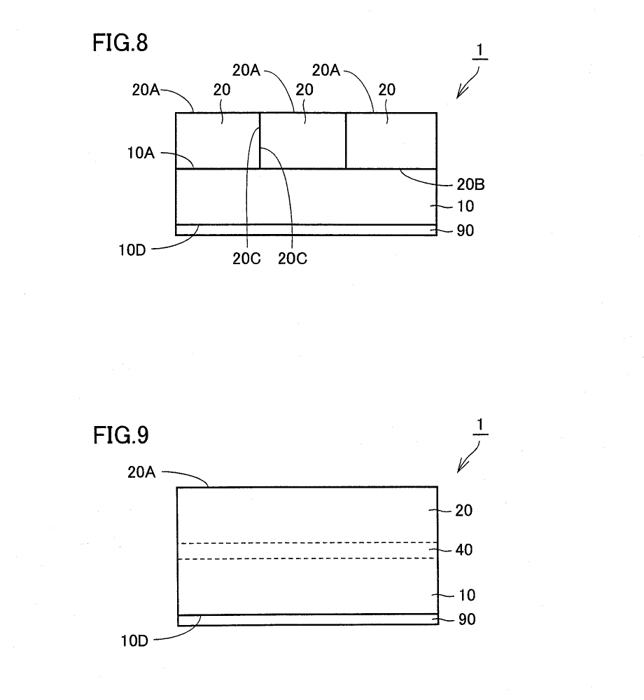

A third embodiment that is another embodiment of the present invention will be described. Referring to FIG. 8, silicon carbide substrate 1 of the third embodiment has a structure basically similar to that of silicon carbide substrate 1 of the first embodiment, and provides similar effects. Silicon carbide substrate 1 of the third embodiment differs from the first embodiment in that a plurality of SiC layers 20 are arranged when viewed in plane.

Referring to FIG. 8, at silicon carbide substrate 1 of the third embodiment, SiC layer 20 is arranged in plurality in plan view. Namely, a plurality of SiC layers 20 are arranged along main surface 10A of base layer 10. Specifically, adjacent SiC layers 20 on base layer 10, among the plurality of SiC layers 20, are arranged in a matrix such that adjacent SiC layers 20 form contact with each other. Accordingly, silicon carbide substrate 1 of the present embodiment can be handled as a substrate of large diameter including SiC layer 20 of high quality. By using this silicon carbide substrate 1, the manufacturing process of a semiconductor device can be rendered effective. Referring to FIG. 8, end faces 20C of adjacent SiC layers 20 are substantially perpendicular to main surface 20A of SiC layer 20. Accordingly, silicon carbide substrate 1 of the present embodiment can be readily manufactured. Silicon carbide substrate 1 of the third embodiment can be manufactured likewise with the first or second embodiment, by arranging a plurality of SiC substrates 20 having end faces 20C substantially perpendicular to main surface 20A, aligned in plane on base substrate 10, in step S30 of the first embodiment, or by holding a plurality of SiC substrates 20 aligned in plane having end faces 20C substantially perpendicular to main surface 20A at first heater 81, in step S50 of the second embodiment.

### Fourth Embodiment

A fourth embodiment that is still another embodiment of the present invention will be described. Referring to FIG. 9, silicon carbide substrate 1 of the fourth embodiment has a structure basically similar to that of silicon carbide substrate 1 of the first embodiment, and provides similar effects. Silicon carbide substrate 1 of the fourth embodiment differs from the first embodiment in that an amorphous SiC layer 40 is formed as an intermediate layer between base layer 10 and SiC layer 20.

Specifically, between base layer 10 and SiC layer 20 in silicon carbide substrate 1 of the fourth embodiment, an amorphous SiC layer 40 made of amorphous silicon carbide is arranged as an intermediate layer. Base layer 10 and SiC layer 20 are connected by amorphous SiC layer 40. The presence of amorphous SiC layer 40 allows a silicon carbide substrate 1 having stacked base layer 10 and SiC layer 20 differing in the concentration of inevitable impurities and/or conductivity type determination impurities to be readily provided.

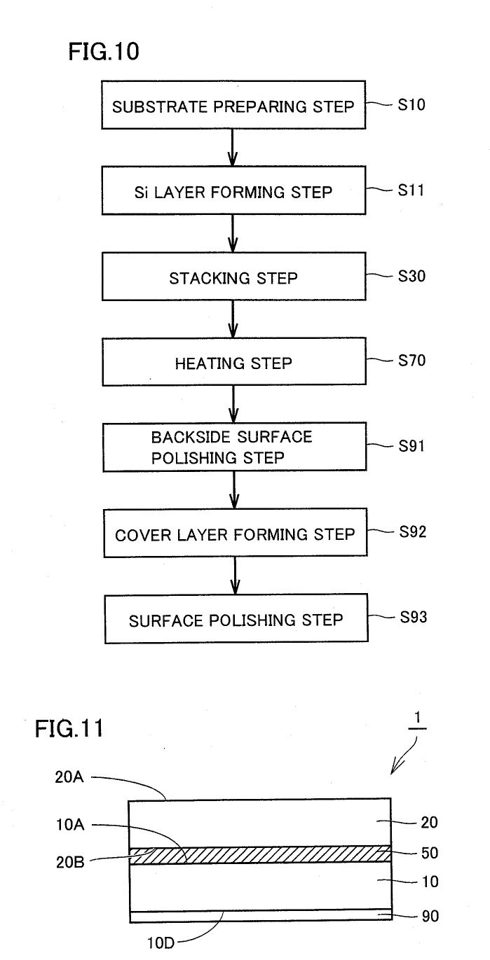

A method for manufacturing silicon carbide substrate 1 of the fourth embodiment will be described with reference to FIG. 10. In the method for manufacturing silicon carbide substrate 1 of the fourth embodiment, a substrate preparing step is performed likewise with the first embodiment at step S10. Base substrate 10 and SiC substrate 20 are prepared. Base substrate 10 is prepared having the concentration of inevitable impurities and the concentration of conductivity type determination impurities higher than those of SiC substrate 20.

Then, an Si layer forming step is performed as step S11. At step S11, an Si layer is formed to a thickness of approximately 100 nm, for example, on one of main surfaces of base substrate 10 prepared in step S10. The Si layer can be formed by, for example, sputtering.

Then, a stacking step is performed as step S30. In this step S30, SiC substrate 20 prepared at step S10 is placed on the Si layer formed at step S11. Accordingly, a stacked substrate is obtained having SiC substrate 20 layered on base substrate 10 with the Si layer thereunder.

Then, a heating step is performed as step S70. At this step S70, the stacked substrate produced at step 30 is heated to approximately 1500° C. in an atmosphere of mixture gas including hydrogen gas and propane gas under the pressure of 1×10³ Pa, for example, and maintained for approximately 3 hours. Accordingly, carbon is supplied by the diffusion mainly from base substrate 10 and SiC substrate 20 to form amorphous SiC layer 40 on the Si layer, as shown in FIG. 9. Thus, step S70 is completed. Subsequently, following step S91, as necessary, likewise with the first embodiment, step S92 is performed. By the process set forth above, silicon carbide substrate 1 shown in FIG. 9 including SiC substrate 20 as SiC layer 20 is completed. Step S93 may also be performed as necessary, likewise with the first embodiment. By the procedure set forth above, silicon carbide substrate 1 of the fourth embodiment including base layer 10 and SiC layer 20 differing in the concentrations of inevitable impurities and/or conductivity type determination impurities, connected by amorphous SiC layer 40, can be manufactured readily.

### Fifth Embodiment

A fifth embodiment that is still another embodiment of the present invention will be described. Referring to FIG. 11, silicon carbide substrate 1 of the fifth embodiment has a structure basically similar to that of silicon carbide substrate 1 of the first embodiment, and provides similar effects. Silicon carbide substrate 1 of the fifth embodiment differs from the first embodiment in that an ohmic contact layer 50 is formed as an intermediate layer between base layer 10 and SiC layer 20.

In silicon carbide substrate 1 of the fifth embodiment, an ohmic contact layer 50 having at least a portion of a metal layer converted to silicide is arranged as an intermediate layer, between base layer 10 and SiC layer 20. Base layer 10 and SiC layer 20 are connected to each other by ohmic contact layer 50. Thus, a silicon carbide substrate 1 having base layer 10 and SiC layer 20 differing in the concentration of inevitable impurities and/or conductivity type determination impurities stacked by virtue of the presence of ohmic contact layer 50 can be readily provided.

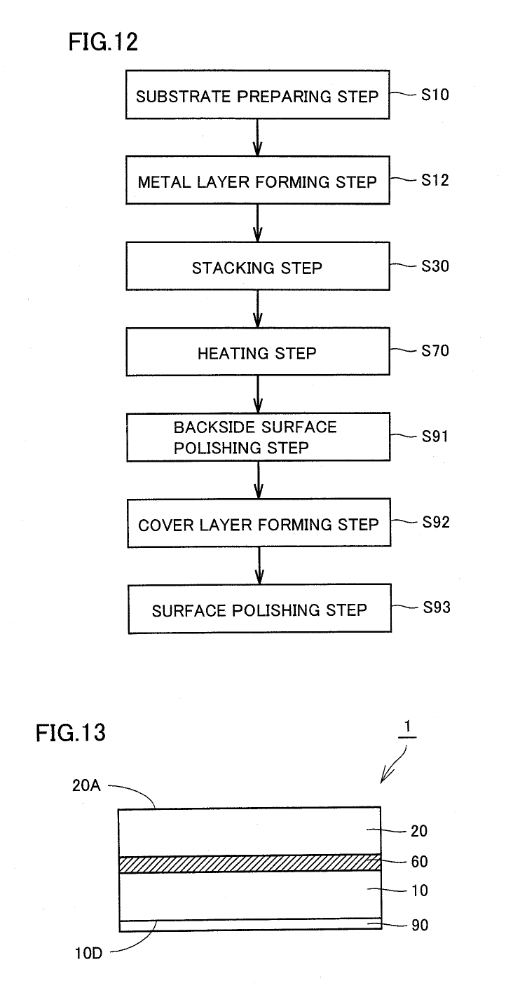

A method for manufacturing silicon carbide substrate 1 of the fifth embodiment will be described hereinafter. Referring to FIG. 12, in the method for manufacturing silicon carbide 1 of the fifth embodiment, a substrate preparing step is performed likewise with the first embodiment at step 10. Base substrate 10 and SiC substrate 20 are prepared. Base substrate 10 is prepared having the concentrations of inevitable impurities and conductivity type determination impurities higher than those of SiC substrate 20.

Then, a metal layer forming step is performed as a step S12. At this step S12, a metal layer is formed by deposition of metal, for example, on one of the main surfaces of base substrate 10 prepared at step S10. The metal layer includes metal that forms silicide by being heated, for example, includes at least one type selected from nickel, molybdenum, titanium, aluminium, and tungsten.

Then, a stacking step is performed as step S30. At step S30, SiC substrate 20 prepared at step S10 is placed on the metal layer formed at step S12. Accordingly, a stacked substrate having SiC substrate 20 stacked on base substrate 10 with a metal layer thereunder is obtained.

Then, a heating step is performed as step S70. At this step S70, the stacked substrate produced at step S30 is heated to approximately 1000° C. in an inert gas atmosphere such as argon. Accordingly, at least a portion of the metal layer (the region in contact with base substrate 10 and the region in contact with the SiC substrate 20) is converted to silicide to form an ohmic contact layer 50. Accordingly, step S70 is completed. Subsequently, following step S91 performed as necessary, likewise with the first embodiment, step S92 is performed. By the process set forth above, silicon carbide substrate 1 shown in FIG. 11, including SiC substrate 20 as SiC layer 20, is completed. Likewise with the first embodiment, step S93 may be performed as necessary. By the procedure set forth above, silicon carbide substrate 1 of the fifth embodiment, including base layer 10 and SiC layer 20 differing in the concentration of inevitable impurities and/or conductivity type determination impurities connected by ohmic contact layer 50, can be readily manufactured.

### Sixth Embodiment

A sixth embodiment that is still another embodiment of the present invention will be described hereinafter. Referring to FIG. 13, silicon carbide substrate 1 of the sixth embodiment has a structure basically similar to that of silicon carbide substrate 1 of the first embodiment, and provides similar effects. Silicon carbide substrate 1 of the sixth embodiment differs from the first embodiment in that a carbon layer 60 is formed as an intermediate layer between base layer 10 and SiC layer 20.

Referring to FIG. 13, silicon carbide substrate 1 of the sixth embodiment differs from the first embodiment in that carbon layer 60 is formed as an intermediate layer between base layer 10 and SiC layer 20. Base layer 10 and SiC layer 20 are connected by carbon layer 60. By virtue of the presence of carbon layer 60, a silicon carbide substrate 1 having base layer 10 and SiC layer 20 differing in the concentration of inevitable impurities and/or conductivity type determination impurities stacked, can be produced readily.

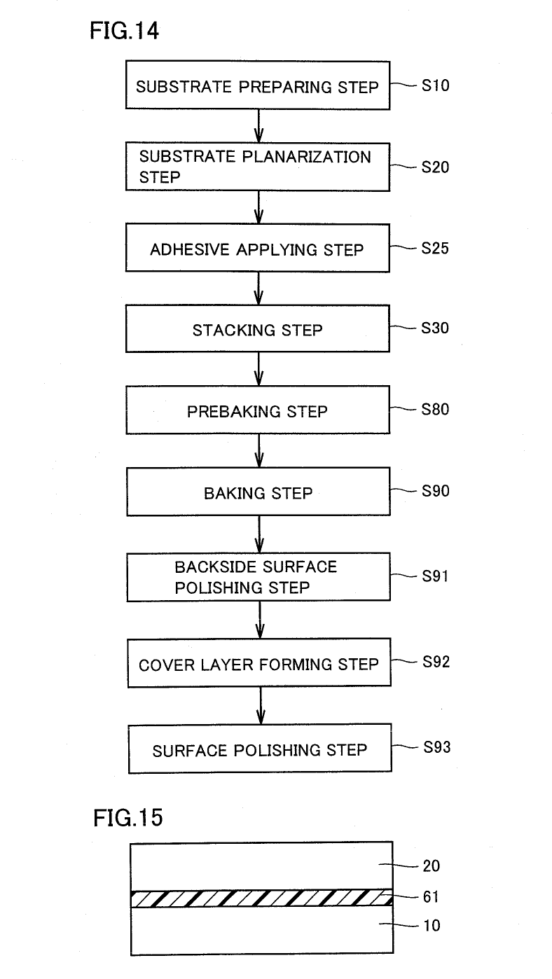

A method for manufacturing silicon carbide substrate 1 of the sixth embodiment will be described hereinafter. Referring to FIG. 14, following step S10, step S20 is performed as necessary, likewise with the first embodiment.

Then, an adhesive applying step is performed as step S25. Referring to FIG. 15, in step S25, a precursor layer 61 is formed by applying a carbon adhesive on the main surface of base layer 10, for example. For the carbon adhesive, an adhesive including, for example, resin, graphite microparticles, and a solvent can be employed. For the resin, resin that becomes non-graphitizable carbon, for example, phenol resin, can be employed. For the solvent, phenol, formaldehyde, ethanol, or the like can be employed. The applied amount of carbon adhesive is preferably greater than or equal to 10 mg/cm² and less than or equal to 40 mg/cm², more preferably greater than or equal to 20 mg/cm² and less than or equal to 30 mg/cm². Further, the thickness of the applied carbon adhesive is preferably less than or equal to 100 μm, more preferably less than or equal to 50 μm.

Then, a stacking step is performed as step S30. In step S30, SiC substrate 20 is placed on and in contact with precursor layer 61 formed on and in contact with the main surface of base layer 10, as shown in FIG. 15, to produce a stacked substrate.

As step S80, a prebaking step is performed. In this step S80, the solvent component is removed from the carbon adhesive constituting precursor layer 61 by heating the stacked substrate. Specifically, the stacked substrate is gradually heated to a temperature range exceeding the boiling point of the solvent component while applying load on the stacked substrate in the thickness direction. This heating is preferably carried out with base substrate 10 and SiC substrate 20 under compression-bonding by means of a clamp or the like. By performing prebaking (heating) as long as time allows, degassing from the adhesive proceeds to allow the adhesion strength to be improved.

Then, a baking step is performed as step S90. At step S90, the stacked substrate having precursor layer 61 prebaked by the heating at step S80 is further heated to a high temperature, preferably higher than or equal to 900° C. and less than or equal to 1100° C., for example to 1000° C., for a period of preferably longer than or equal to 10 minutes and less than or equal to 10 hours, for example for 1 hour, whereby precursor layer 61 is baked. As the atmosphere for baking, an inert gas atmosphere of argon or the like is employed. The pressure of the atmosphere is the atmospheric pressure, for example. Accordingly, precursor layer 61 becomes carbon layer 60 made of carbon to complete step S90. Then, following step S91, as necessary, likewise with the first embodiment, step S92 is performed. By the process set forth above, silicon carbide substrate 1 shown in FIG. 13, including base substrate 10 as base layer 10 and SiC substrate 20 as SiC layer 20, is completed. Likewise with the first embodiment, step S93 may be performed, as necessary. By the procedure set forth above, silicon carbide substrate 1 of the sixth embodiment, including base layer 10 and SiC layer 20 differing in the concentration of inevitable impurities and/or conductivity type determination impurities connected by carbon layer 60, can be manufactured readily.

The fourth to sixth embodiments have been described based on, but not limited to, amorphous SiC layer 40, ohmic contact layer 50, and carbon layer 60, as an intermediate layer. Another intermediate layer capable of connecting base layer 10 to SiC layer 20 may be employed.

In silicon carbide substrate 1 set forth above, the structure of the silicon carbide constituting SiC layer 20 is preferably the hexagonal type, more preferably 4H—SiC. Base layer 10 and SiC layer 20 (as well as adjacent SiC layers 20 when there are a plurality of SiC layers 20) are preferably formed of silicon carbide single crystal having the same crystal structure. By employing silicon carbide single crystal of the same crystal structure for base layer 10 and SiC layer 20, the physical properties such as the thermal expansion coefficient or the like are set uniform, allowing suppression of the generation of warpage at silicon carbide substrate 1, separation between base layer 10 and SiC layer 20, or separation between SiC layers 20, in the manufacturing process of silicon carbide substrate 1 or a semiconductor device using silicon carbide substrate 1

Furthermore, for SiC layer 20 and base layer 10, the angle between the c-axes of the silicon carbide single crystal constituting each layer is preferably less than 1°, more preferably less than 0.1°. Moreover, it is desirable that the c plane in the silicon carbide single crystal is not rotated in plane.

The diameter of base layer (base substrate) 10 is preferably greater than or equal to 2 inches, more preferably greater than or equal to 6 inches. The thickness of silicon carbide substrate 1 is preferably greater than or equal to 200 μm and less than or equal to 1000 μm, more preferably greater than or equal to 300 μm and less than or equal to 700 μm. The resistivity of SiC layer 20 is preferably less than or equal to 50 mgΩcm, more preferably less than or equal to 20 mΩcm.

### Seventh Embodiment

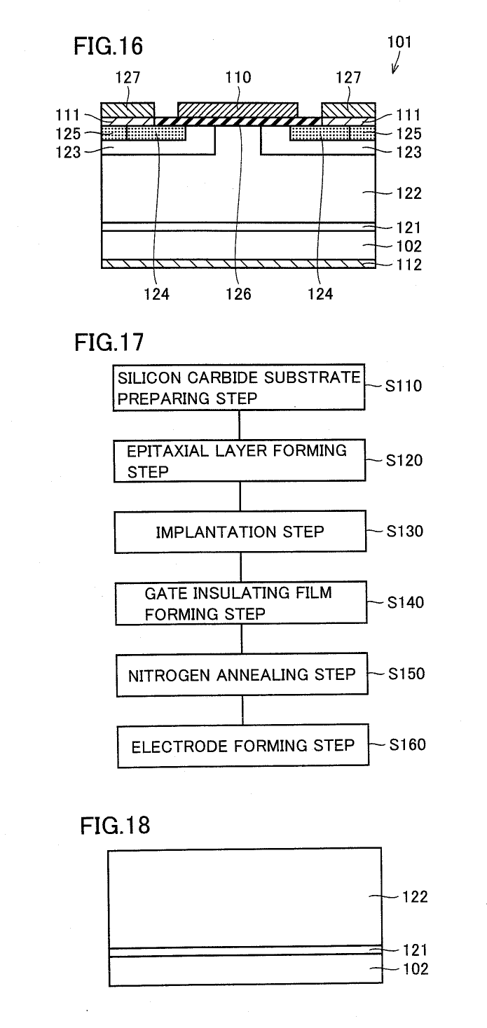

An example of a semiconductor device produced using a silicon carbide substrate of the present invention set forth above will be described hereinafter as the seventh embodiment. Referring to FIG. 16, a semiconductor device 101 of the present invention is a vertical double implanted MOSFET (DiMOSFET), including a substrate 102, a buffer layer 121, a breakdown voltage holding layer 122, a p region 123, an n⁺ region 124, a p′ region 125, an oxide film 126, a source electrode 111 and an upper source electrode 127, a gate electrode 110, and a drain electrode 112 formed at the backside surface of substrate 102. Specifically, buffer layer 121 made of silicon carbide is formed on the surface of substrate 102 made of n type conductivity silicon carbide. For substrate 102, a silicon carbide substrate of the present invention including silicon carbide substrate 1 described in the first to sixth embodiments set forth above is employed. In the case where silicon carbide substrate 1 of the first to sixth embodiments is employed, buffer layer 121 is formed on SiC layer 20 of silicon carbide substrate 1. Buffer layer 121 has an n type conductivity, and a thickness of 0.5 μm, for example. The concentration of conductivity type determination impurities of the n type in buffer layer 121 is set at 5×10¹⁷ cm⁻³, for example. Breakdown voltage holding layer 122 is formed on buffer layer 121. Breakdown voltage holding layer 122 is made of n type conductivity silicon carbide, and has a thickness of 10 μm, for example. The concentration of the conductivity type determination impurities of the n type in breakdown voltage holding layer 122 may take the value of 5×10¹⁵ cm⁻³, for example.

At the surface of breakdown voltage holding layer 122, p regions 123 having p type conductivity are formed spaced apart from each other. In p region 123, n⁺ region 124 is formed at the surface layer of the region 123. At a region adjacent to this n⁺ region 124, p⁺ region 125 is formed. There is also an oxide film 126 formed extending from above n⁺ region 124 at one of p regions 123, over p region 123, a region of breakdown voltage holding layer 122 exposed between the two p regions 123, the other p region 123, as far as above n⁺ region 124 at the relevant other p region 123. Gate electrode 110 is formed on oxide film 126. Source electrode 111 is formed on n⁺ region 124 and p⁺ region 125. Upper source electrode 127 is formed on source electrode 111. Substrate 102 has drain electrode 112 formed at a backside surface that is the surface opposite to the surface where buffer layer 121 is formed.

In semiconductor device 101 of the present embodiment, a silicon carbide substrate of the present invention such as silicon carbide substrate 1 described in the first to sixth embodiments is employed as substrate 102. Specifically, semiconductor device 101 includes substrate 102 as the silicon carbide substrate, buffer layer 121 and breakdown voltage holding layer 122 as the semiconductor layer formed by epitaxial growth on substrate 102, and source electrode 111 formed on breakdown voltage holding layer 122. Substrate 102 is a silicon carbide substrate of the present invention such as silicon carbide substrate 1. The silicon carbide substrate of the present invention is a silicon carbide substrate capable of reducing the manufacturing cost of a semiconductor device employing a silicon carbide substrate. Therefore, semiconductor device 101 is a semiconductor device having the manufacturing cost reduced.

A method for manufacturing semiconductor device 101 of FIG. 16 will be described with reference to FIGS. 17-21. Referring to FIG. 17, first a silicon carbide substrate preparing step (S110) is performed. At this stage, a substrate 102 made of silicon carbide having the (03-38) plane as the main surface (refer to FIG. 18) is prepared. For substrate 102, a silicon carbide substrate of the present invention including silicon carbide substrate 1 manufactured by the manufacturing method described in the first to sixth embodiments is prepared as substrate 102.

For substrate 102 (refer to FIG. 18), a substrate having n type conductivity and a substrate resistance of 0.02 Ωcm may be employed.

Then, as shown in FIG. 17, an epitaxial layer forming step (S120) is performed. Specifically, buffer layer 121 is formed on the surface of substrate 102. This buffer layer 121 is formed on main surface 20A of SiC layer 20 of silicon carbide substrate 1 (refer to FIGS. 1, 8, 9, 11 and 13) employed as substrate 102. For buffer layer 121, an epitaxial layer made of silicon carbide of n type conductivity, and having a thickness of 0.5 μm, for example, is formed. The concentration of conductivity type determination impurities in buffer layer 121 may take the value of 5×10¹⁷ cm⁻³, for example. On this buffer layer 121, breakdown voltage holding layer 122 is formed, as shown in FIG. 18. For breakdown voltage holding layer 122, a layer of n type conductivity silicon carbide can be formed by epitaxial growth. The thickness of breakdown voltage holding layer 122 may take the value of 10 μm, for example. The concentration of the conductivity type determination impurities of the n type in breakdown voltage holding layer 122 may take the value of 5×10¹⁵ cm⁻³, for example.

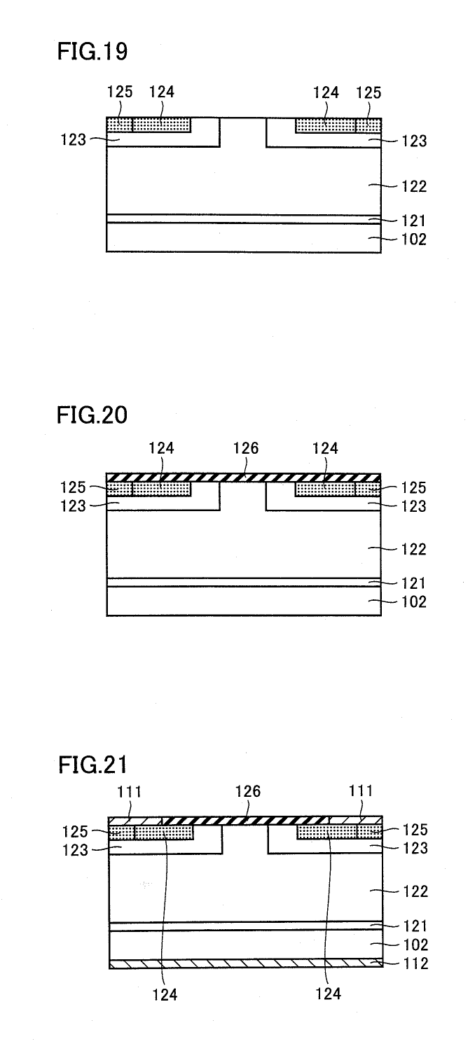

Then, an implantation step (S130) shown in FIG. 17 is performed. Specifically, using an oxide film formed by photolithography and etching as a mask, conductivity type determination impurities of p type conductivity are implanted into breakdown voltage holding layer 122 to form p region 123, as shown in FIG. 19. Following removal of the oxide film used, a new oxide film having a pattern is formed by photolithography and etching. Using this oxide film as a mask, conductivity type determination impurities of n type are implanted into a predetermined region to form n⁺ region 124. Further, by implanting p conductivity type determination impurities through a similar procedure, p⁺ region 125 is formed. As a result, the configuration as shown in FIG. 19 is obtained.

Following the implantation step, an activation annealing process is performed. For this activation annealing process, the conditions including a heating temperature of 1700° C., and a heating duration of 30 minutes, using argon gas, for example, as the atmosphere gas, may be employed.

Then, a gate insulating film forming step (S140) is performed, as shown in FIG. 17. Specifically, oxide film 126 is formed on to cover breakdown voltage holding layer 122, p region 123, and n⁺ region 124, and p⁺ region 125, as shown in FIG. 20. The condition for forming oxide film 126 may include, for example, dry oxidation (thermal oxidation). The conditions of this dry oxidation including a heating temperature of 1200° C. and a heating duration of 30 minutes may be employed. At this stage, the separation of inevitable impurities from the base layer to be introduced into oxide film 126 can be suppressed even when the concentration of the inevitable impurities in the base layer is high since the silicon carbide substrate of the present invention employed as substrate 102 has a cover layer formed. As a result, increase of fixed charge or movable ions in oxide film 126 is suppressed, allowing the threshold voltage of manufactured semiconductor device 101 (MOSFET) to be stable.

Then, a nitrogen annealing step (S150) is performed, as shown in FIG. 17. Specifically, annealing is performed with nitric oxide (NO) as the atmosphere gas. The annealing conditions include, for example, 1100° C. for the heating temperature and 120 minutes for the heating duration. As a result, nitrogen atoms are introduced in the proximity of the interface between oxide film 126 and underlying breakdown voltage holding layer 122, p region 123, n⁺ region 124 and p⁺ region 125. Following this annealing step using nitric oxide as the atmosphere gas, further annealing using argon (Ar) as the inert gas may be performed. Specifically, the conditions including a heating temperature of 1100° C. and a heating duration of 60 minutes, using argon gas as the atmosphere gas, may be employed.

Then, an electrode forming step (S160) indicated in FIG. 17 is performed. Specifically, a resist film having a pattern is formed by photolithography on oxide film 126. Using this resist film as a mask, the region of the oxide film located above n⁺ region 124 and p⁺ region 125 is removed by etching. Then, a conductor film such as of metal is formed in contact with n⁺ region 124 and p⁺ region 125 on the resist film and in an opening formed in oxide film 126. Then, the conductor film located on the resist film is removed (lift off) by removing the resist film. Nickel (Ni), for example, may be employed for the conductor. As a result, source electrode 111 and drain electrode 112 can be obtained, as shown in FIG. 21. At this stage, a heat treatment is preferably carried out for alloying. Specifically, a heat treatment (alloying process) is carried out at a heating temperature of 950° C. and a heating duration of 2 minutes using argon (Ar) gas that is inert gas for the atmosphere gas.

Then, upper source electrode 127 (refer to FIG. 16) is formed on source electrode 111. Further, gate electrode 110 (refer to FIG. 16) is formed on oxide film 126. Thus, semiconductor device 101 shown in FIG. 16 can be obtained. Namely, semiconductor device 101 is produced by forming an epitaxial layer and electrodes on SiC layer 20 of silicon carbide substrate 1.

Although a vertical MOSFET has been described as an example of a semiconductor device that can be produced using the silicon carbide substrate of the present invention in the seventh embodiment set forth above, the semiconductor device that can be produced is not limited thereto. Various semiconductor devices such as a junction field effect transistor (JFET), an insulated gate bipolar transistor (IGBT), or a schottky barrier diode can be produced using a silicon carbide substrate of the present invention. Furthermore, although the seventh embodiment has been described based on a semiconductor device being produced by forming an epitaxial layer functioning as an active layer on a silicon carbide substrate with the (03-38) plane as the main surface, the crystal plane that can be employed for the main surface is not limited thereto. An arbitrary crystal plane according to the usage, including the (0001) plane, may be employed.

Furthermore, by employing a main surface having an off angle relative to the (0-33-8) plane in the <01-10> direction greater than or equal to −3° and less than or equal to +5° as the main surface (main surface 20A of SiC substrate (SiC layer) 20 of silicon carbide substrate 1), the channel mobility in the case of producing a MOSFET or the like using a silicon carbide substrate can be further improved. As used herein, the (0001) plane and the (000-1) plane of the hexagonal single crystal silicon carbide are defined as the silicon plane and the carbon plane, respectively. Further, “the off angle relative to the (0-33-8) plane in the <01-10> direction” refers to the angle between the orthogonal projection of the normal line of the main surface on the plane defined by the <000-1> direction and the <01-10> direction as the reference of the off orientation, and the normal line of the (0-33-8) plane. The sign is positive when the aforementioned orthogonal projection approaches the <01-10> direction in parallel, and negative when the aforementioned orthogonal projection approaches the <000-1> direction in parallel.

A main surface having an off angle relative to the (0-33-8) plane in the <01-10> direction greater than or equal to −3° and less than or equal to +5° implies a plane on the carbon plane side satisfying the aforementioned conditions in the silicon carbide crystal. The (0-33-8) plane in the present application includes the plane of the equivalent carbon plane side differing in representation by the setting of the axis to define the crystal plane, and does not include a plane of the silicon plane side.

### Example

Upon actually producing silicon carbide substrates of the present invention, experiments were carried out to confirm the typical concentration of inevitable impurities in the base layer and cover layer. First, a silicon carbide substrate having a configuration similar to that of silicon carbide substrate 1 shown in FIG. 1 was produced according to procedures likewise with those of the first embodiment. Cover layer 90 was formed by CVD epitaxial growth. Referring to FIG. 1, the concentration of inevitable impurities at main surface 10D of base layer 10 and main surface 90A of cover layer 90 were analyzed using secondary ion mass spectrometer (SIMS). The results are shown in Table 1.

TABLE 1

| | Fe | Al | Ca | Ti | V | B |
|---|---|---|---|---|---|---|
| Base layer | 3.8 × 10¹⁶ | 2.3 × 10¹⁶ | 7.2 × 10¹⁴ | 4.4 × 10¹⁵ | 2.3 × 10¹⁴ | 2.0 × 10¹⁶ |
| Cover layer | N.D. | 5.0 × 10¹³ | N.D. | N.D. | N.D. | 1.0 × 10¹⁴ |

Table 1 shows the concentration of iron (Fe), aluminium (Al), calcium (Ca), titanium (Ti), vanadium (V) and boron (B) at main surface 10D of base layer 10 and main surface 90A of cover layer 90. The concentration unit is cm⁻³. The notation “N.D.” in Table 1 implies that the concentration was below the detection limit.

It is appreciated from Table 1 that, although the concentration of inevitable impurities in the base layer is high, the concentration of inevitable impurities at the surface of the cover layer is significantly lowered down to a level that will not affect the properties of the semiconductor device, even in the case where a silicon carbide substrate is used for manufacturing a semiconductor device. It is therefore confirmed that the formation of a cover layer in the silicon carbide substrate of the present invention allows sufficient suppression of the mixture of inevitable impurities into the semiconductor device caused by the separation of inevitable impurities from the main surface of the base layer.

The silicon carbide substrate, semiconductor device, and method for manufacturing a silicon carbide of the present invention are particularly applicable advantageously to a silicon carbide substrate, semiconductor device, and method for manufacturing a silicon carbide, requiring reduction in the manufacturing cost.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate comprising:
a base layer made of silicon carbide;
an SiC layer made of single crystal silicon carbide, arranged on said base layer, and having a concentration of inevitable impurities lower than the concentration of inevitable impurities in said base layer; and
a cover layer made of silicon carbide, formed on a main surface of said base layer at a side opposite to said SiC layer, having the concentration of inevitable impurities lower than the concentration of inevitable impurities in said base layer.

2. The silicon carbide substrate according to claim 1, wherein said base layer and said cover layer are of identical type conductivity.

3. The silicon carbide substrate according to claim 1, wherein said cover layer has a concentration of conductivity type determination impurities higher than 1×10¹⁸ cm⁻³.

4. The silicon carbide substrate according to claim 1, wherein said base layer has a thickness greater than the thickness of said cover layer.

5. The silicon carbide substrate according to claim 1, wherein
said base layer has a concentration of conductivity type determination impurities higher than 2×10¹⁹ cm⁻³, and
said SiC layer has the concentration of conductivity type determination impurities higher than 5×10¹⁸ cm⁻³ and lower than 2×10¹⁹ cm⁻³.

6. The silicon carbide substrate according to claim 5, further comprising an epitaxial growth layer made of single crystal silicon carbide, formed on said SiC layer,
wherein a stacking defect density in said epitaxial growth layer is lower than the stacking defect density in said base layer.

7. The silicon carbide substrate according to claim 1, wherein conductivity type determination impurities in said base layer differ from the conductivity type determination impurities in said SiC layer.

8. The silicon carbide substrate according to claim 1, wherein conductivity type determination impurities in said base layer include nitrogen or phosphorus, and
conductivity type determination impurities in said SiC layer include nitrogen or phosphorus.

9. The silicon carbide substrate according to claim 1, wherein said SiC layer is aligned in plurality in plan view.

10. The silicon carbide substrate according to claim 1, wherein
said base layer is made of single crystal silicon carbide, and
a full width at half maximum of an x-ray rocking curve of said SiC layer is smaller than the full width at half maximum of the x-ray rocking curve of said base layer.

11. The silicon carbide substrate according to claim 1, wherein
said base layer is made of single crystal silicon carbide, and
a micropipe density of said SiC layer is lower than the micropipe density of said base layer.

12. The silicon carbide substrate according to claim 1, wherein
said base layer is made of single crystal silicon carbide, and
a dislocation density of said SiC layer is lower than the dislocation density of said base layer.

13. The silicon carbide substrate according to claim 1, wherein said base layer includes a single crystal layer made of single crystal silicon carbide so as to include a main surface at a side facing said SiC layer.

14. The silicon carbide substrate according to claim 13, wherein a full width at half maximum of an x-ray rocking curve of said SiC layer is smaller than the full width at half maximum of the x-ray rocking curve of said single crystal layer

15. The silicon carbide substrate according to claim 13, wherein said SiC layer has a micropipe density lower than the micropipe density of said single crystal layer.

16. The silicon carbide substrate according to claim 13, wherein said SiC layer has a dislocation density lower than the dislocation density of said single crystal layer.

17. The silicon carbide substrate according to claim 1, wherein an off angle of a main surface of said SiC layer at a side opposite to said base layer, relative to a {0001} plane is greater than or equal to 50° and less than or equal to 65°.

18. The silicon carbide substrate according to claim 17, wherein an angle between an off orientation of a main surface of said SiC layer at the side opposite to said base layer and a <1-100> direction is less than or equal to 5°.

19. The silicon carbide substrate according to claim 18, wherein the off angle of a main surface of said SiC layer at the side opposite to said base layer, relative to a {03-38} plane in the <1-100> direction is greater than or equal to −3° and less than or equal to 5°.

20. The silicon carbide substrate according to claim 17, wherein an angle between an off orientation of a main surface of said SiC layer at the side opposite to said base layer and a <11-20> direction is less than or equal to 5°.

21. A semiconductor device comprising:
a silicon carbide substrate;
a semiconductor layer formed on said silicon carbide substrate by epitaxial growth; and
an electrode formed on said semiconductor layer,
said silicon carbide substrate being a silicon carbide substrate defined in claim 1.

22. A method for manufacturing a silicon carbide substrate comprising the steps of:
preparing an SiC substrate made of single crystal silicon carbide;
arranging a silicon carbide source so as to face one of main surfaces of said SiC substrate;
forming a base layer made of silicon carbide and having a concentration of inevitable impurities higher than the concentration of inevitable impurities than said SiC substrate, in contact with one of main surfaces of said SiC substrate, by heating said silicon carbide source; and
forming a cover layer made of silicon carbide, and having the concentration of inevitable impurities lower than the concentration of inevitable impurities in said base layer, on a main surface of said base layer at a side opposite to said SiC substrate.

23. The method for manufacturing a silicon carbide substrate according to claim 22, wherein said cover layer is formed by CVD epitaxial growth.

24. The method for manufacturing a silicon carbide substrate according to claim 22, further comprising the step of polishing a main surface of said base layer at a side opposite to said SiC substrate, prior to said step of forming a cover layer.
